(19) United States
(12) Patent Application Publication
(10) Pub. No.: US 2023/0229870 A1
(43) Pub. Date: Jul. 20, 2023

(54) CROSS COUPLED CAPACITOR ANALOG IN-MEMORY PROCESSING DEVICE

(71) Applicant: Khalifa University of Science and Technology, Abu Dhabi (AE)

(72) Inventors: Dima KILANI, Abu Dhabi (AE); Baker MOHAMMAD, Abu Dhabi (AE)

(21) Appl. No.: 17/998,346

(22) PCT Filed: May 19, 2021
(86) PCT No.: PCT/IB2021/054330

§ 371 Date: Nov. 9, 2022

Related U.S. Application Data
(60) Provisional application No. 63/027,681, filed on May 20, 2020.

(51) Int. Cl. G06G 7/16

(52) U.S. Cl. CPC G06G 7/16

(57) ABSTRACT

A system for performing analog multiply-and-accumulate (MAC) operations employs at least one cross coupling capacitor processing unit (C3PU). A system includes a wordline to which an analog input voltage is applied, a voltage supply line having a supply voltage (VDD), a bitline, a clock signal line, a current integrator op-amp connected to the bitline and to the clock signal line, and a C3PU connected to the wordline. The C3PU includes a CMOS transistor and a capacitive unit. The capacitive unit includes a cross coupling capacitor and a gate capacitor. The cross coupling capacitor is connected between the wordline and the gate terminal of the CMOS transistor. The gate capacitor is connected between the gate terminal and ground. The CMOS transistor is configured to conduct a current that is proportional to voltage applied to the gate terminal.

### BACKGROUND

Multiply-and-accumulate (MAC) units are building blocks of digital processing units that may be used in many applications including artificial intelligence (AI) for edge devices, signal/image processing, convolution, and filtering. Recently, the focus on AI implementation on edge devices is increasing as edge devices improve and AI techniques advance. AI on edge devices is capable to address difficult machine learning problems using deep neural network (DNN) architectures. However, DNN algorithms are computationally intensive, with large data sets and high memory bandwidth. This results in a memory access bottleneck that introduces considerable energy and performance overheads.

### BRIEF SUMMARY

The following presents a simplified summary of some embodiments of the invention in order to provide a basic understanding of the invention. This summary is not an extensive overview of the invention. It is not intended to identify key/critical elements of the invention or to delineate the scope of the invention. Its sole purpose is to present some embodiments of the invention in a simplified form as a prelude to the more detailed description that is presented later.

In many embodiments, a cross-coupling capacitor processing unit (C3PU) supports analog mixed signal in-memory computing to perform multiply-and-accumulate (MAC) operations. In embodiments, the C3PU includes a capacitive unit, a CMOS transistor, and a voltage-to-time converter (VTC). The capacitive unit can serve as a computational element that holds a multiplier operand and performs multiplication once an input voltage corresponding to a multiplicand is applied to an input terminal of the VTC. The input voltage is converted by the VTC to a pulse width signal. The CMOS transistor transfers the multiplication. A demonstrator including a 5×4 array of the C3PUs is presented. The demonstrator is capable of implementing 4 MACs in a single cycle. The demonstrator was verified using Monte Carlo simulation in 65 nm technology. The 5×4 C3PU demonstrator consumed an energy of 66.4 fJ/MAC at 0.3 V voltage supply. The demonstrator exhibited an error of 5.4%. The demonstrator exhibited low energy consumption and occupies a smaller area by 3.4 times and 2.4 times, respectively, with similar error value when compared to a digital-based 8×4-bit fixed point MAC unit. The 5×4 C3PU demonstrator was used to implement an artificial neural network (ANN) for performing iris flower classification and achieved a 90% classification accuracy compared to ideal accuracy of 96.67% using MATLAB.

Deep neural networks (DNNs) are approximate in nature and many AI applications can tolerate lower accuracy. This opens the opportunity for potential tradeoffs between energy efficiency, accuracy, and latency.

One direction to eliminate the need for explicit memory access is to utilize in-memory computing (IMC) architectures, which has significant advantages in energy efficiency and through-put over conventional counterparts based on von Neumann architecture. Both Digital and analog approaches for IMC have been proposed. An artificial neural network (ANN) using analog implementation has the potential to outperform the digital-based neural networks in energy efficiency and speed. One key component in an analog implemented ANN is a synaptic memory that is utilized for weight storage. Several weight storage approaches have been proposed including: 1) traditional volatile memory including SRAM and DRAM, 2) non-volatile memory including CMOS-based flash memory, emerging technology, and Resistive RAM (RRAM) such as memristor, and 3) analog mixed signal (AMS) using capacitors and transistors. Both SRAM and DRAM are limited to high power devices that are not suitable for duty-cycled edge devices. The flash memory traps the weight charges in the floating gate, which is electrically isolated from the control gate. On the other hand, the emerging technology of memristors stores the weight as a conductance value. Memristors, however, suffer from low endurance and sneak path, which results in a state disturbance. AMS using capacitors and transistors has been demonstrated for storing weights as charges and for control of the conductance of the transistors. AMS, however, requires relatively a large and complex biasing circuit to control the charges on the capacitor in addition to non-linearity due to the variations of the drain-to-source voltage of the transistor. SRAM has been used both as memory and cross-coupling capacitor as a computational element to perform binary MAC operation using bitwise XNOR gate. The advantage of the cross-coupling computation is that it helps in reducing the inaccuracy of the AMS circuits since the capacitor has lower power consumption and process variation.

A cross-coupling capacitor (C3) computing, hence, named, C3 processing unit (C3PU) coupled with a voltage-to-time converter (VTC) circuitry is described herein that implements AMS MAC operation. The C3PU utilizes a cross-coupling capacitor for IMC as both a memory and a computational element to perform AMS MAC operation. The C3PU can be utilized in applications that heavily rely on vector-matrix multiplications including but not limited to ANN, CNN, and DSP. The C3PU is suitable for applications with fixed coefficients such as weights on pre-trained CNN or image compression.

In many embodiments, a 5.7 μW low power voltage-to-time converter (VTC) is implemented at the input voltage terminal of the C3PU to generate a modulated pulse width signal. In many embodiments, the VTC is used to produce a linear multiplication operation.

A 5×4 crossbar architecture based on C3PU was designed and simulated in 65 nm technology to employ 4 MACs where each MAC performs 5 multiplications and 4 additions. Simulation results show that the energy efficiency of the 5×4 C3PU is 66.4 fJ/MAC at 0.3 V voltage supply with an error compared to computation in MATLAB of less than 5.4%.

A 5×4 crossbar architecture was used to implement a two-layer ANN for performing iris flower classification. The synaptic weights were trained offline and then mapped into capacitance ratio values for the inference phase. The ANN classifier circuit was designed and simulated in 65 nm CMOS technology. It achieved a high inference accuracy of 90% compared to a baseline accuracy of 96.67% obtained from MATLAB.

### BRIEF DESCRIPTION OF THE DRAWINGS

FIG. 1 is a circuit diagram of an example cross-coupling capacitor processing unit (C3PU) configured for analog mixed signal in-memory computing to perform multiply-and-accumulate (MAC) operations in voltage domain, in accordance with embodiments of the present disclosure.

FIG. 2 is a circuit diagram of an example cross-coupling capacitor processing unit (C3PU) configured for analog mixed signal in-memory computing to perform multiply-and-accumulate (MAC) operations in time domain using a voltage-to-time converter (VTC), in accordance with embodiments of the present disclosure.

FIG. 3 is a plot of drain source current (Ids) versus Vg for the C3PU of FIG. 1 and FIG. 2.

FIG. 4 is a circuit diagram of an example VTC for the C3PU of FIG. 2.

FIG. 5 is a circuit diagram of the VTC of FIG. 4 illustrating operation in a sampling phase.

FIG. 6 is a circuit diagram of the VTC of FIG. 4 illustrating operation in an evaluation phase.

FIG. 7 is a detailed circuit diagram of an embodiment of the VTC of FIG. 4 that is implemented using CMOS.

FIG. 8 is a plot illustrating input/output waveforms of the VTC of FIG. 7.

FIG. 9 is a plot illustrating modulated pulse width signal Vpw for different Vin values for the VTC of FIG. 7.

FIG. 10 is a plot illustrating observed (simulation) and expected (ideal) output time delay (tpw) versus the input voltage (Vin) for the VTC of FIG. 7.

FIG. 11 is a plot illustrating mismatch variations on the time delay obtained from Monte Carlo simulation at Vin=0.2 V for the VTC of FIG. 7.

FIG. 12 is a plot illustrating mismatch variations on the time delay obtained from Monte Carlo simulation at Vin=1.0 V for the VTC of FIG. 7.

FIG. 13 is a circuit diagram showing an example 5×4 C3PU crossbar architecture in accordance with embodiments of the present disclosure.

FIG. 14 is a plot illustrating distribution of MAC output from column 4 of the C3PU crossbar architecture of FIG. 13.

FIG. 15 depicts algorithm flow of an artificial neural network (ANN) classifier for an iris flower data set illustrating the functional signals carried in the forward pass (interference) phase.

FIG. 16 illustrates a detailed circuit design implementation of the time domain subtractor and activation function (ReLU) followed by digital block (of the ANN classifier of FIG. 15) to increase the signals' pulse width by a constant factor of 20×.

FIG. 17 is a plot illustrating waveform of the time domain subtractor and ReLU function (of the ANN classifier of FIG. 15) when V₁>V₄.

### DETAILED DESCRIPTION

In the following description, various embodiments of the present invention will be described. For purposes of explanation, specific configurations and details are set forth in order to provide a thorough understanding of the embodiments. However, it will also be apparent to one skilled in the art that the present invention may be practiced without the specific details. Furthermore, well-known features may be omitted or simplified in order not to obscure the embodiment being described.

According to various embodiments of the present disclosure, techniques for in-memory computing (IMC) can include implementations of synaptic memory that is utilized for weight storage in an artificial neural network in an analog system. According to certain specific embodiments, to implement analog MAC operation, a cross-coupling capacitor processing unit (C3PU) is provided having a circuit design using a crossbar architecture.

Example C3PU Circuit and Operation

The following sections discuss the design details and operation of an example C3PU. The A coupling capacitance is used to transfer apply a voltage to the gate of the transistor. Current is passed through the transistor based on the voltage applied to the gate of the transistor.

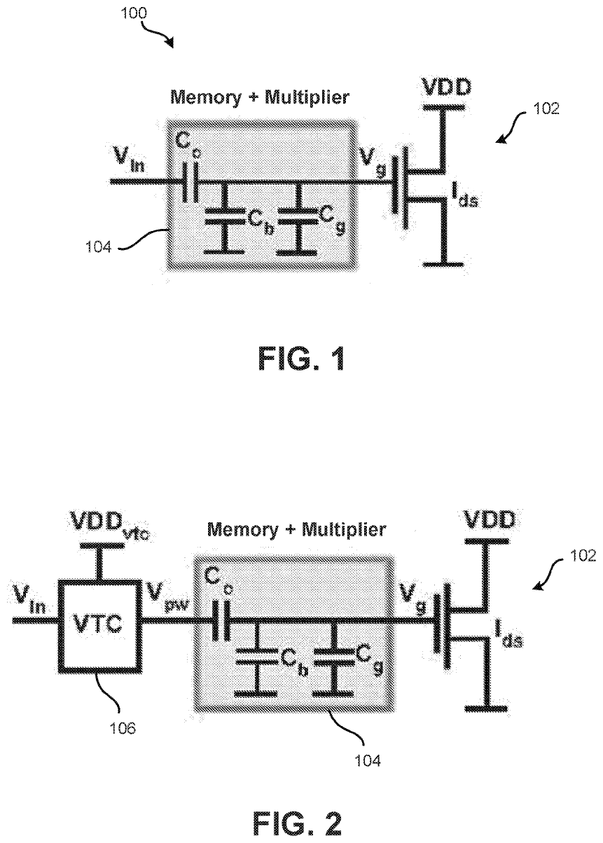

Turning now to the drawing figures in which similar reference identifiers refer to similar elements, FIG. 1 shows an example C3PU 100 that performs in-memory multiplication operation. The C3PU 100 includes a CMOS transistor 102 and a capacitive unit 104. The capacitive unit 104 includes a cross-coupling capacitor (Cc), a capacitor (Cb) connected between the gate of the transistor 102 and ground and a gate capacitor (Cg). A modulated input voltage amplitude (Vin) (which corresponds to a first multiplication operand) is applied at an input terminal of the capacitive unit 104. A second operand is stored in the capacitive unit 104 as an equivalent capacitance ratio Xeq=Cc/(Cc+Cb+Cg). The capacitive computational unit multiplies the two operands and generates a voltage Vg that is a function of Vin, Cc, Cb and Cg as given in Eq. 1. Vg is applied to the gate of CMOS transistor 102 producing a drain source current (Ids) as given in Eq. 2 where Gm is the transistor's trans-conductance. Ids is proportional to the multiplication of its two operands Vin and Xeq. Since the multiplication is linear, the transistor 102 must also operate in linear mode in order to transfer the multiplication correctly to the output in an electrical current form.

$${V}_{g} = {V}_{i n} \frac{{C}_{c}}{{C}_{c} + {C}_{b} + {C}_{g}} \qquad ( 1 )$$

$${I}_{d s} = {G}_{m} \times {V}_{g} = {G}_{m} \times {V}_{i n} \frac{{C}_{c}}{( {C}_{c} + {C}_{b} + {C}_{j} )} \qquad ( 2 )$$

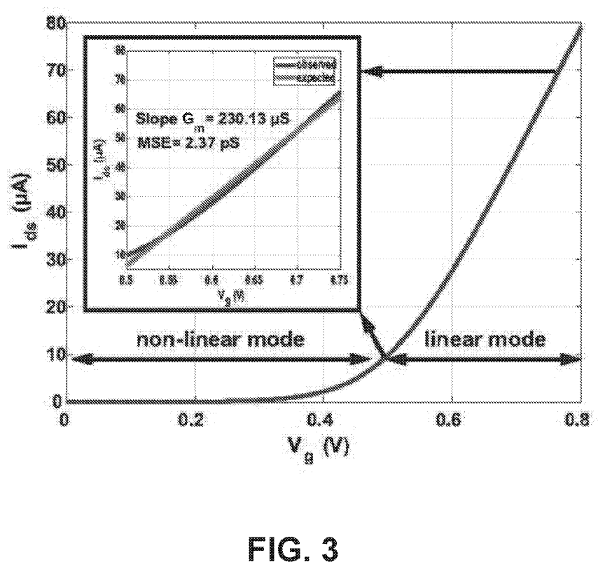

The value of Vg determines the operational mode of the transistor 102 and affects its trans-conductance value and hence its linearity. FIG. 3 depicts the Ids of the transistor 102 versus Vg at VDD=0.3 V. The transistor operates either in linear or non-linear mode based on the multiplication output of the two operands. As shown in FIG. 3, Ids is approximately linear only when Vg is between 0.5 V and 0.8 V with a trans-conductance slope of 230.13 μS and a mean square error (MSE) of 2.37 pS between the observed and expected ones. The linearity over a small range of Vg creates some design constraints. First, the input voltage has to be selected within a certain high value range. This means that Vin requires normalization to tolerate the low Vin values resulting in a mapping error. Second, even though Vin is high, the capacitance ratio (Xeq) should be also high enough providing large Vg value to run the transistor in linear mode.

To overcome the former issues that significantly affect the functionality of the C3PU multiplier, the analog input voltage can be processed in time domain rather than voltage domain. This can be achieved using a voltage-to-time converter (VTC) 106 as shown in FIG. 2 to convert the amplitude of analog input Vin into time delay to generate a modulated pulse width signal (Vpw). This way, the voltage level of Vpw is ensured to be high having a value equal to the VTC's supply voltage VDDvtc=1.0 V. Consequently, the transistor 102 will always operate in linear mode giving that Xeq is selected within a certain high range between 0.5 and 0.75 and, VDD is low with a value of 0.3 V. If Xeq >0.75, then the value of Vg will saturate. The resultant Ids becomes a function of Vpw as shown in Eq. 3 that is linearly proportional to time delay. The VTC circuit design as discussed below achieves high conversion linearity over a wide range of Vin. This guarantees that the C3PU performs a valid multiplication between Vin and Xeq by providing a linear conversion from Vin to Vpw and running the transistor 102 in linear mode.

$${I}_{d s} = {G}_{m} \times {V}_{g} = {G}_{m} \times {V}_{p w} \frac{{C}_{c}}{( {C}_{c} + {C}_{b} + {C}_{g} )} \qquad ( 3 )$$

Presenting the data Vin in time domain has several advantages where both time and capacitance scale better with technology than voltage. In addition, it has less variations and provides better noise immunity compared voltage domain where the signal-to-noise ratio is degraded due to voltage scaling.

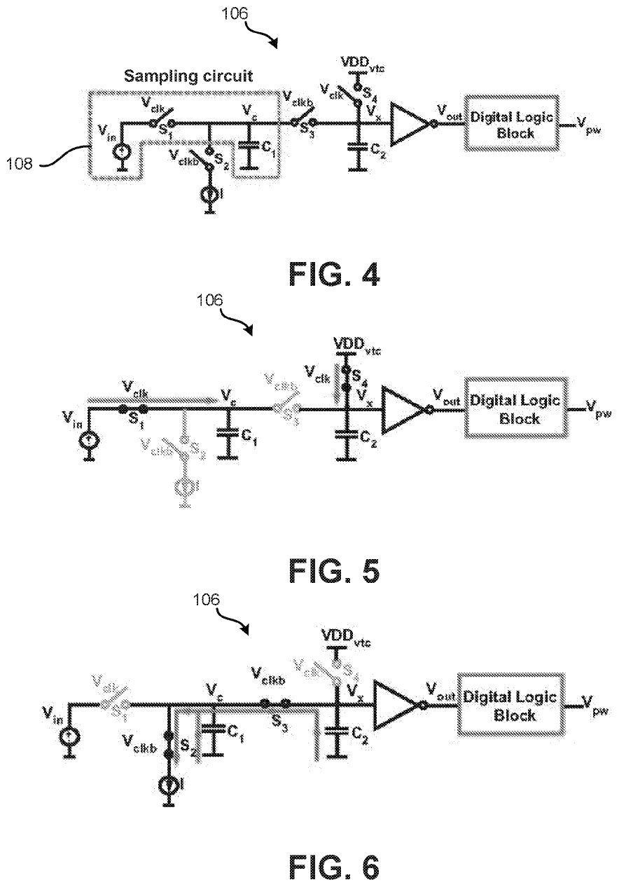

FIG. 4 shows the block diagram of an example VTC circuit 106. The VTC circuit 106 includes a sampling circuit 108, an inverter, and a current source. In order to achieve voltage-to-time conversion, the VTC 106 has two operating phases: sample and evaluate. The basic principle is to transfer the input voltage into a capacitor during the sample phase and then discharge this capacitor through a current source during the evaluate phase. A simple inverter is used to transfer the time it takes to discharge the capacitor into delay. The delay is linearly proportion to the input voltage.

During the sampling phase as shown in FIG. 5: S1 and S4 turn on when the clock Vclk=1.0 V and S2 and S3 are off when the inverted clock Vclkb=0. The capacitor C1 is pre-charged with a voltage Vc equal to the input voltage value Vin. The capacitor C2 is charged with a voltage Vx equal to the supply voltage V Dvtc. During the evaluation phase as shown in FIG. 6: S1 and S4 turn off when the clock Vclk=0 and S2 and S3 turn on when Vclkb=1.0 V. The node Vc is coupled to Vx. In this phase, the functionality of the VTC 106 depends on Vin. When Vin is high (i.e. Vin=VDDvtc), Vc=Vx and the initial charge across the capacitors is Qi=VDD(C1+C2). When Vin is small (i.e. Vin=0), the initial charge across the capacitors is Q=VinC1+VDDC2. Due to the potential difference between C1 and C2, the charges are shared among them. Consequently, the current flows from C2 to C1 causing a voltage pump on Vc. Then, it starts discharging through the current source I till it reaches the switching point of the inverter Vsp resulting in a final charge Qf=Vsp(C1+C2). After that, the inverter pulls up the delayed output voltage Vout. The time it takes to discharge Vx to the inverter's switching point voltage is referred to time delay t_{d}. This time delay, given in Eq. 4, depends on four main parameters: voltage values of VDDvtc and Vin, voltage value of Vsp, C1 and C2, and the average current Iavg till it is discharged. The Vsp value is set by the aspect ratio of PMOS and NMOS transistors of the inverter

$$( \frac{{β}_{n}}{{β}_{p}} )$$

as given in Eq. 5. The Iavg value depends on the amount of charge stored in the capacitors, which varies linearly with Vin given that VDDvtc is fixed. Thus, t_{d} has a linear relationship with Vin. Equation. 6 shows the time delay when Vin=VDDvtc, which depends on the difference between VDDvtc and Vsp.

$${t}_{d} = \frac{{Q}_{i} - {Q}_{f}}{{I}_{a v g}} = \frac{{C}_{1} {V}_{i n} + {C}_{2} V D {D}_{vtc} - {V}_{s p} ( {C}_{1} + {C}_{2} )}{{I}_{a ν g}} \qquad ( 4 )$$

$${V}_{s p} = \frac{V D {D}_{vtc} - \vert {V}_{t h p} \vert + \sqrt{\frac{{β}_{n}}{{β}_{p}}} {V}_{t h n}}{1 + \sqrt{\frac{{β}_{n}}{{β}_{p}}}} \qquad ( 5 )$$

$${t}_{d} = \frac{( V D {D}_{vtc} - {V}_{s p} ) ( {C}_{1} + {C}_{2} )}{{I}_{a v g}} {V}_{i n} = V D {D}_{vtc} \qquad ( 6 )$$

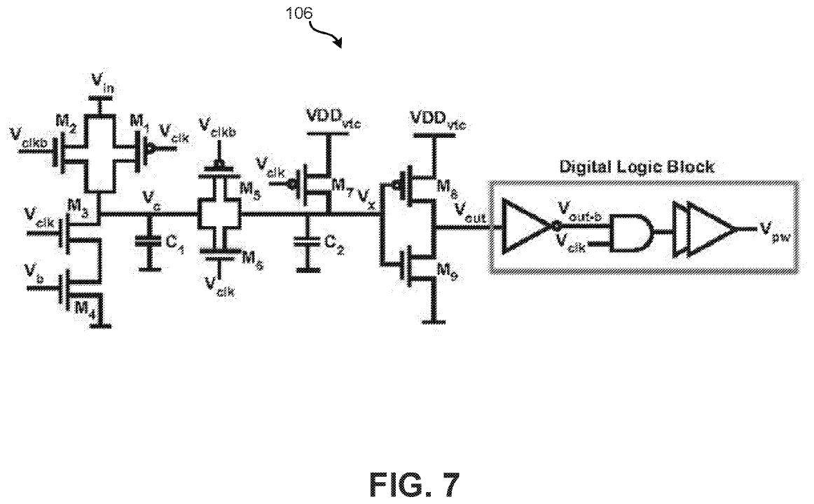

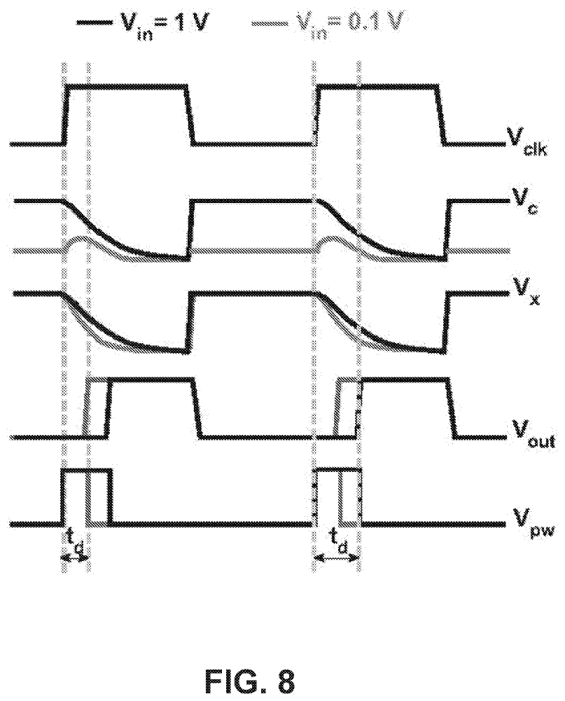

FIG. 7 shows a detailed circuit diagram of an embodiment of the VTC 106 that is implemented using CMOS. The switches S1 and S3 are replaced by pass gates (M1, M2) and (M5, M6), respectively. The switches S2 and S4 are replaced by M3 and M7, respectively. The current source is simply implemented using M4 and controlled by a bias voltage Vb to operate in saturation region. The inverter is realized by M8 and M9. In order to generate a pulse width signal Vpw, a digital logic block of inverter and AND gate is added. During the sampling phase when Vclk=0 and Vclkb=1, M3 is off and M7 is on so that C2 is charged to VDDvtc. The pass gate (M1,M2) turns on to precharge C1 with Vc=Vin. The pass gate (M5,M6) is off, which disconnects the node Vx from Vc to eliminate the short circuit current on the delay chain at low voltage levels of Vin. At this phase, Vx=VDDvtc, which makes Vout=0. During the evaluation phase when Vclk=1.0 and Vclkb=0, the pass gate (M5,M6) and M3 turn on whereas the pass gates (M1, M2) and M7 turn off. In the evaluation phase, Vc is coupled to Vx and the charge redistributes between C1 and C2. Initially, if Vin<VDD, Vc<Vx. As a result, a current flows from C2 to C1 making a charge pump on Vc as shown in FIG. 8 (see gray waveform when Vin=0.1 V). If Vin=VDDvtc, Vc follows Vx as shown FIG. 8 when Vin=1.0 V. In both cases, the capacitor current starts discharging through M4 equating it with the drain source current of M4, Ids4. This drops the value of Vx till it reaches Vsp of the inverter (M8, M9). Then, it pulls up Vout that is connected to an inverter chain whose output Vout-b is ANDED with Vclk to generate Vpw. FIG. 8 depicts the waveforms of the VTC 106. Note that the VTC 106 controls the delayed Vout at the rising edge of Vclk.

The VTC circuit 106 was designed, implemented, and simulated in 65 nm industry standard CMOS technology. The input voltage is set between 0.1 V to 1.0 V at VDDvtc=1.0 V. so that linear voltage-to-time conversion is achieved. The capacitors C1 and C2 and the transistor M4 are sized to support a minimum time delay of 165 ps at the minimum Vin of 0.1 V. Metal insulator metal (MIM) capacitors of C1=27 fF and C2=10 fF are utilized. The M4 size of 500 nm/140 nm controlled by its gate voltage of Vb=0.5 V provides a current source of 14 μA. The inverter is carefully sized to provide the desired Vsp. Hence, the aspect ratio of M9 is 5 times the aspect ratio of M8 such that Vsp=0.35 V. Table 1 summarizes the specifications of the VTC design.

TABLE 1
Specifications of the VTC.

| | |
|---|---|
| VDD_{vtc} (V) | 1 |
| Vᵢₙ (V) | [0-1] |
| C₁ (fF) | 27 |
| C₂ (fF) | 10 |
| W_{1 ,2, 5, 6}/L_{1, 2, 5, 6} (nm/nm) | 600/60 |
| W_{3, 7}/L_{3, 7} (nm/nm) | 200/60 |
| W₄/L₄ (nm/nm) | 500/140 |
| W₈/L₈ (nm/nm) | 200/60 |
| W₉/L₉ (μm/nm) | 1/60 |
| V_{b} | 0.5 V |
| Vₛₚ | 0.35 V |

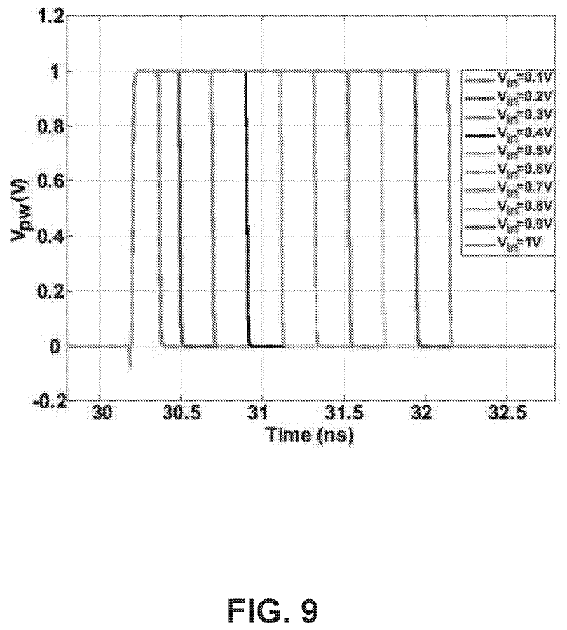

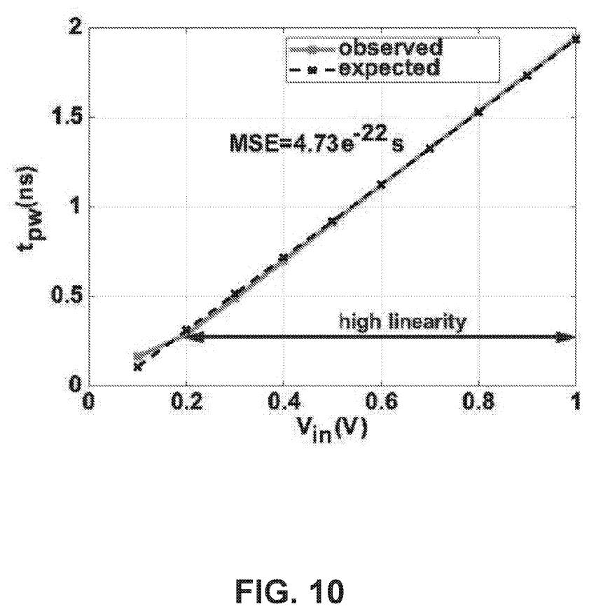

FIG. 9 depicts the modulated pulse width signal V_{PW} at different Vin values. As shown in FIG. 9, the pulse width varies from 0.165 ns at Vin=0.1 V to 1.95 ns at Vin=1.0 V resulting in a conversion gain of 1.98 ns/V. FIG. 10 shows the output time delay t_{pw} from the VTC versus the input voltage observed from the simulation in addition to the expected ones. As depicted in FIG. 10, the time delay is linearly proportional to the input voltage. It has a low MSE value of 4.73e⁻²² s, a low power consumption of 5.7 μW including the clock buffers and a small area of 0.001 mm².

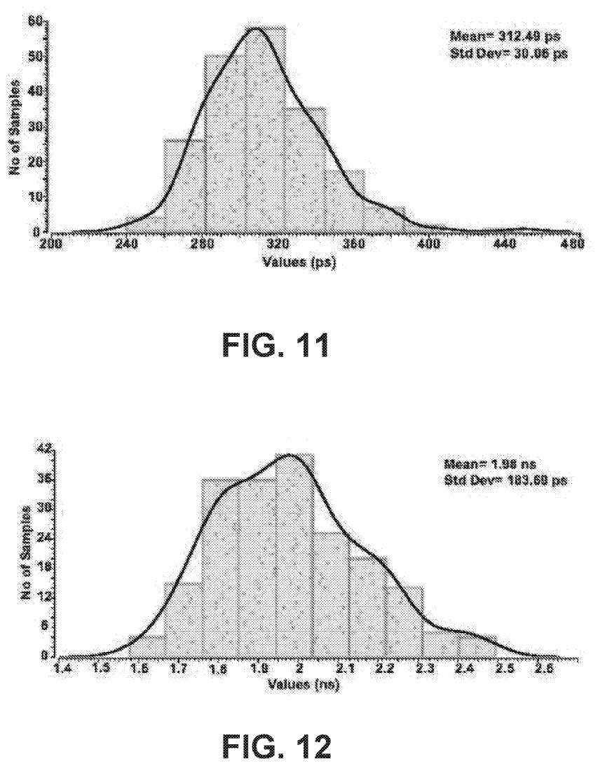

To quantify the impact of process variation on pulse width value, Monte Carlo Spice simulation with 200 samples and with mismatch model is investigated. FIG. 11 and FIG. 12 show the impact of mismatch variations on the time delay obtained from Monte Carlo simulation at Vin=0.2 V and Vin=1.0 V, respectively. As shown, the standard deviation in both cases is low −30.06 ps from the mean of 312.49 ps at Vin=0.2 V and 183.69 ps from the mean of 1.98 ns at Vin=1.0 V. The ratio of standard deviation to the mean is approximately 11%.

Example C3PU Crossbar Architecture for IMC Applications

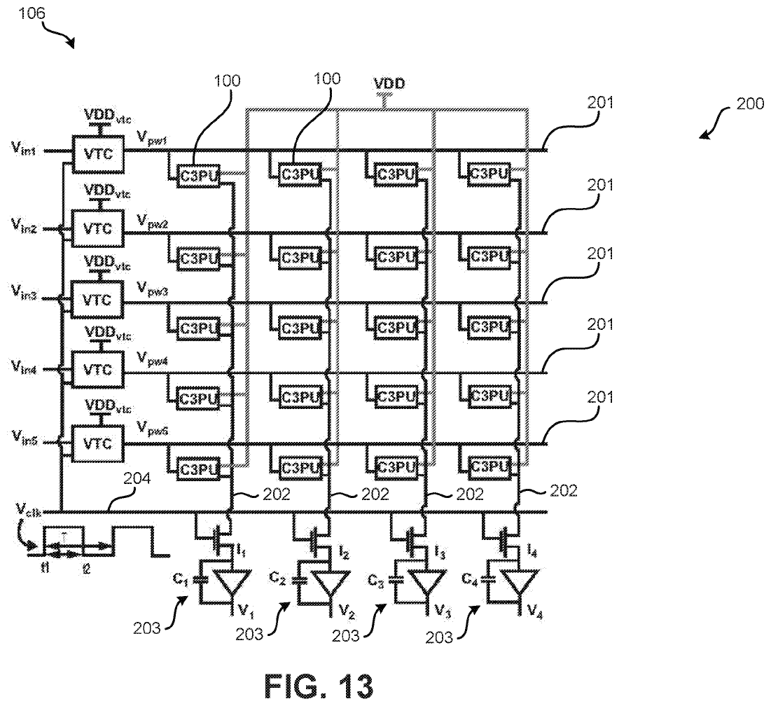

FIG. 13 is a circuit diagram showing an example 5×4 C3PU crossbar architecture 200 that includes instances of the C3PU 100. Computational crossbars support high throughput and energy efficiency since they inherently support parallel operations, and can naturally realize a vector-matrix operation with significant savings compared to digital counterparts. Energy efficiency is achieved by performing MAC operations in the same place where the data is stored. The transistor source in each C3PU computational element 100 is connected to a supply voltage VDD. Input voltages V_{in,1-5} are first converted into modulated pulse width signals V_{pw,1-5} using 5 separate VTCs_, which are configured and operate as discussed above. Each of the V_{pw,1-5} is applied to respective wordline 201 that is connected to each of a row of C3PU computational blocks 100 in order to run each of the C3PU computational blocks 100 in the row in linear mode. The current produced by each of the C3PUs 100 is a product of the multiplication of Vpw;i and capacitance ratio Xeq;ij (where i is the row and j is the column) and then, summed by a shared bitline 202. The resulting currents I₁₋₄ represent the full MAC calculation of each column.

The operation of the example 5×4 C3PU crossbar architecture 200 depends on two phase functions: computation and isolation. In the computation phase when the clock signal Vclk=1, the MAC operation is achieved by multiplying the V_{pw,i} pulse widths with the capacitance ratios C_{c,ij}/(C_{c,ij}+C_{b,ij}+C_{g,ij}). Then, the transistors transfer this multiplication into current that is summed on each bitline. The summed currents are integrated over a period of time t₁-t₂ using a virtual ground current integrator op-amp in order to provide the outputs as voltage levels V₁₋₄ as given in Eq. 7.

$${V}_{j} = \frac{1}{{C}_{j}} {\int }_{t 1}^{t 2} {I}_{j} ( d t ) = \frac{1}{{C}_{j}} {\int }_{t 1}^{t 2} {Σ}_{t = 1}^{t = 2} {I}_{ds , ij} \qquad ( 7 )$$

The value of output voltages depends on two main parameters: a) time that the current will be accumulated t₁-t₂ and b) capacitor size Cⱼ. The time t1-t2 can be fixed and represent the pulse width of the clock. This time is set to be greater than the maximum pulse width of V_{pw,i}. The maximum pulse width of V_{pw} is approximately 2 ns when the maximum input voltage Vᵢₙ=1. Thus, the pulse width of the clock can be set to 3 ns to ensure the computation and accumulation of the currents. In addition, the Cⱼ size plays an important role in determining the scaling factor that is required to approximately allow V₁₋₄ to reach the expected output levels. The scaling factor is calculated by dividing the obtained MAC output voltages V₁₋₄ by the expected values and hence the Cⱼ size is set. Once the approximate voltages are achieved, the C3PU elements are isolated from the outputs by setting V_{clk}=0 to enter the isolation phase. The isolation phase is essential in order to allow the functionality of the VTC and to initialize the output stage of a virtual ground op-amp 203. The period T including computation and isolation time taken to operate the MAC calculations is 6 ns. Table 2 shows the specifications of the C3PU crossbar architecture 200.

TABLE 2
5 × 4 C3PU Crossbar Specifications

| | |
|---|---|
| VDD (V) | 0.3 |
| Vᵢₙ (V) | 1 |
| V_{pw} (V) | 1 |
| t_{pw} (ns) | 0-2 |
| X_{eq} | 0.5-0.75 |
| V_{g} (V) | 0.5-0.75 |
| T (ns) | 6 |
| Transistor size | 500 nm/60 nm |

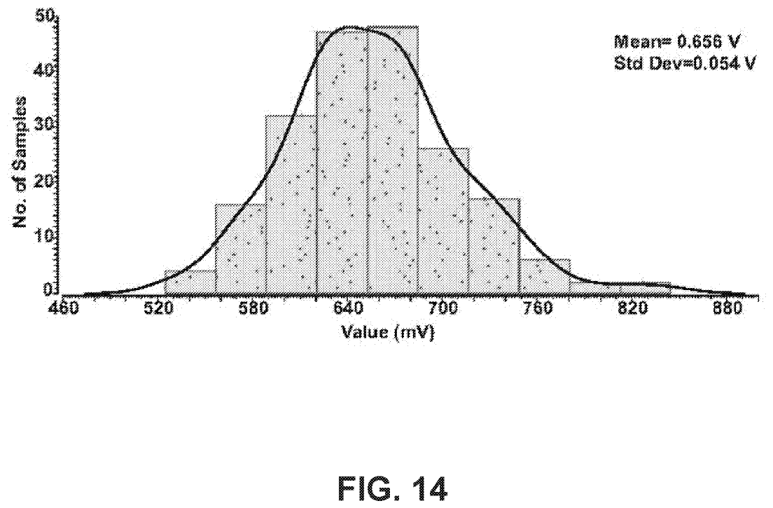

The 5×4 C3PU crossbar architecture 200 can be implemented employing 65 nm technology. The input voltages can be fed to the C3PU crossbar architecture 200 for 30 continuous clock cycles. Each cycle can have different sets of input voltage levels that are converted into modulated pulse width signals. FIG. 14 shows the distribution of MAC output from column 4. The output V4 has a mean value μ of 0.656 V and standard deviation σ of 54 mV with a 8.23% variation. The minimum a value is 7.3 mV at output voltage=0.0 V and the maximum σ is 77 mV at output voltage=0.97 V. Monte Carlo simulation reports an average error of 5.4% for the 30 input samples by comparing the observed MAC output from simulation with the expected values. The energy efficiency of the 5×4 C3PU crossbar architecture 200 and the 5 VTC blocks is 26.3 fJ/MAC and 40.1 fJ/MAC, respectively, resulting in a total energy efficiency of 66.4 fJ/MAC. Each MAC operation includes 5 multiplications and 4 additions. To further increase the number of operations, the crossbar array size can be enlarged. Some design constraints need to be considered when increasing the C3PU crossbar size. Adding more rows including the C3PU raises the accumulated currents, which requires larger capacitor size in the integrator circuit to achieve the desired output voltage. For example, every additional 5 rows demand an additional 300 fF capacitor. Therefore, there is a tradeoff between the number of rows and the integrator's capacitor size. Increasing the number of columns is also limited as the resistance line affect the driving signal of the V_{pw}. The resistance due to the line connected from the VTCs to the columns increases with the number of columns and this degrades the pulse width of V_{pw} signal. Simulation results show that a C3PU crossbar with 32 columns will suppress the pulse width of V_{pw} by 10.8%. The maximum number of columns that the C3PU crossbar can afford is 46 with a degradation of 13.4% in the pulse width.

In order to evaluate the 5×4 C3PU crossbar architecture 200, a 5×4 fixed point (FXP) crossbar units have been implemented using ASIC design flow in 65 nm CMOS. Table 3 shows the 3×3-bit, 4×4-bit, 8×4-bit and 8×8-bit FXP crossbars performance compared to the 5×4 C3PU crossbar 200. The error of the C3PU crossbar 200, 5.6%, is approximately close to the error of the 8×4-bit MAC unit, 6.52%. However, the advantage of the C3PU crossbar 200 is the lower energy and area consumption by 3.4 times and 2.4 times compared with the 8×4-bit MAC unit.

TABLE 3
Evaluation of 5 × 4 FXP crossbar MAC units
with differnet input and weight resolutions.

| MAC Unit | Energy | Error | Area |
|---|---|---|---|
| Type | (fJ/MAC) | (%) | (μm²/MAC) |
| 3 × 3-bit | 60.9 | 64.7 | 127.7 |
| 4 × 4-bit | 107 | 10 | 246.2 |
| 8 × 4-bit | 226.2 | 6.52 | 655.8 |
| 8 × 8-bit | 526 | 0.74 | 1380.7 |
| C3PU | 66.4 | 5.6 | 277.1 |

C3PU Demonstrator For ANN Applications

The advantage of the C3PU 100 is demonstrated by accelerating the MAC operations found in an ANN using an iris flower database. The iris flower data set consists of 150 samples in total divided equally between the three different classes of the iris flower namely, Setosa, Versicolour, and Virginica. Each sample holds the following features all in cm: sepal length, sepal width, petal length, and petal width. The architecture of the ANN consists of two layers: four nodes for the input layer each representing one of the input features, followed by three hidden neurons and lastly three output neurons for each class. In order to implement the MAC operations in the ANN, the iris features are considered as the first operands and are mapped into voltage values. The weights are considered as second operands and are stored as capacitance ratios in the capacitive unit of the C3PU. A simple linear mapping algorithm is used between the neural weights and capacitance ratios.

The training phase is performed offline using MATLAB by dividing the data set between training and testing as 80% and 20%, respectively. Post-training weights can have values with both positive and negative polarities. Hence, before mapping these weights into capacitance ratio values, they need to be shifted by the minimum weight value wₘᵢₙ. After performing the multiplication between the inputs and shifted weights, the effect of the shifting operation must be removed by subtracting the following term from all weights Σᵢ₌₁ⁿ=IN×|Wₘᵢₙ|, where IN is the input to the hidden/output layer and n is the number of input nodes. Mapping such operation into C3PU architecture requires adding an additional column to the hidden and output crossbars to store the wₘᵢₙ value in each layer.

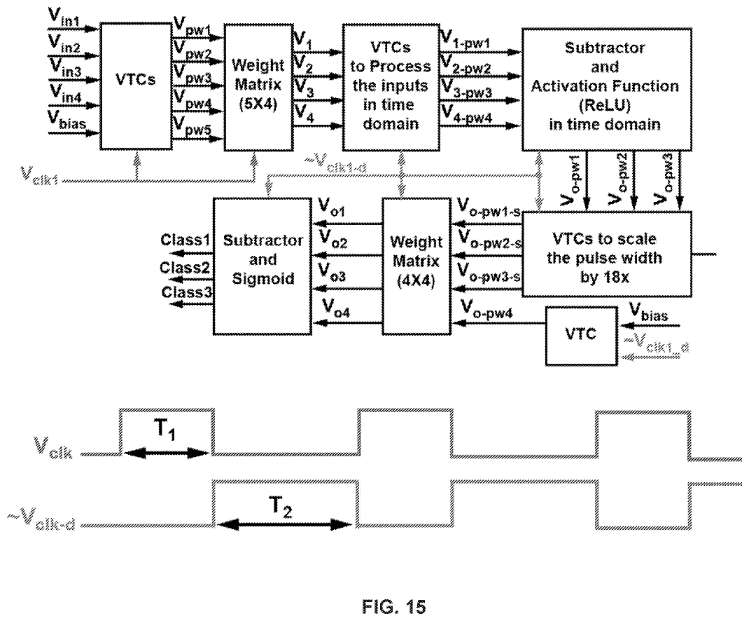

FIG. 15 depicts the algorithm flow of the ANN classifier for iris flower data set. It has two operational phases: phase 1 and phase 2. In phase 1, when V_{clk}=1.0 and ˜V_{clk-d}=0.0, the inputs are processed in the first layer. In phase 2, when V_{clk}=0.0 and ˜V_{clk-d}=1, the outputs from the first layer are taken and processed in the second layer to generate the required output iris flower classes. In phase 1, the iris flower data set (which includes four features) is mapped into four voltage levels Vᵢₙ₁₋₄. These voltages are then converted into four pulse width modulated signals V_{pw1-4} using four VTC blocks discussed above. The bias voltage V_{bias} added as an input to better fit the ANN model and is also converted into a pulse width modulated signal V_{pw5}. The V_{pw1-5}, first operands, are connected to the 5×4 weight matrix C3PU as explained previously with respect to FIG. 13. The weights, second operands, in this case are stored as equivalent capacitance ratios X_{eq} in the C3PU. The output voltages V₁₋₄ from the current integrator used at the end of each column in the C3PU weight matrix will act as inputs to the second layer. The current integrator inherently takes care of the scaling factor which is decided depending on the factor between the shifted output values from a neural network and the output from the C3PU. This is important in order to compensate for the mapping between the values.

Once V₁₋₄ are generated, the classifier switches to phase 2 in order to process them to the second layer. But before that, the impact of shift operation that is implemented on the weights needs to be removed by subtracting V₄ from V₁₋₃. Then, the subtracted outputs are passed through Relu activation function. In the ANN classifier, the subtraction operation and Relu function are implemented in time domain. In order to achieve such implementation, V₁₋₄ are first converted to pulse width modulated signals using VTCs and then passed to the time domain subtractor and Relu activation function to generate V_{o-pw1-3}. These output signals may have small pulse widths due to the subtraction operation which does not correspond to the expected subtraction outputs. Therefore, the pulse widths of the V_{o-pw1-3} are scaled by a constant factor depending on the expected subtraction output from the ANN using MATLAB and the observed outputs from the ANN using C3PU. After that, the scaled pulse width signals V_{o-pw1-3-s} are fed to the 4×4 C3PU weight matrix. The output voltages from the weight matrix Vₒ₁₋₄ are passed to the subtractor and then softmax function in order to generate the proper class based on the input features.

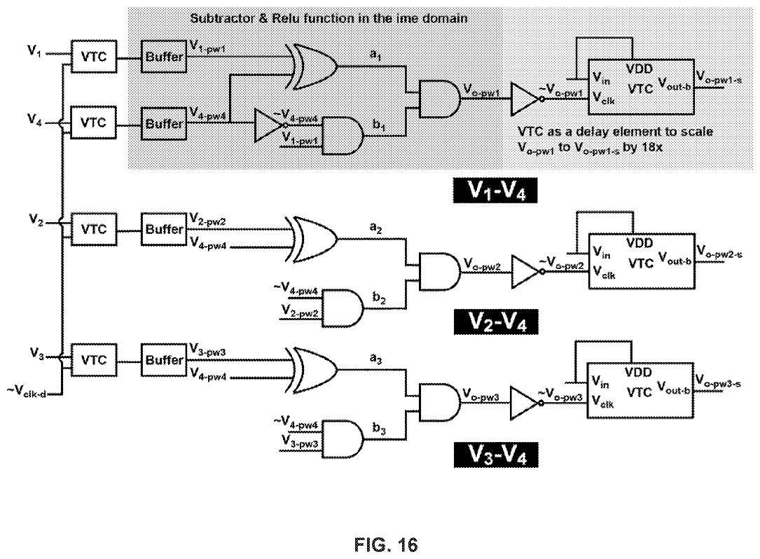

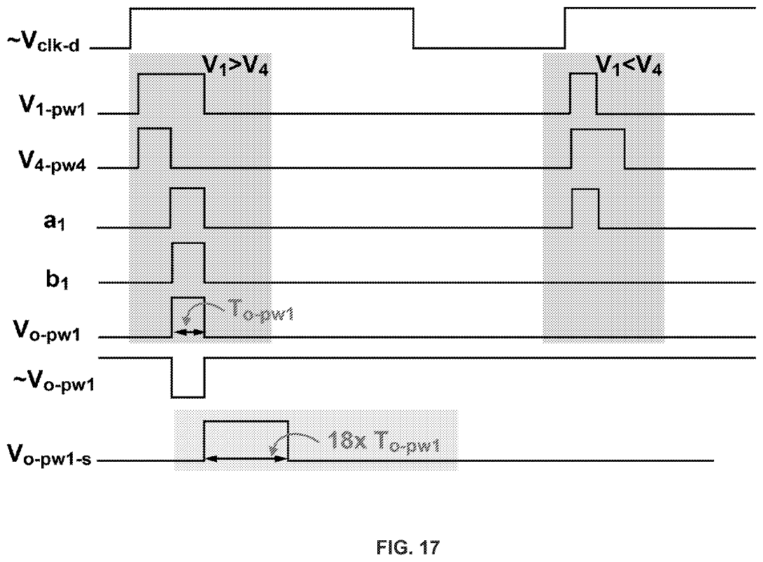

FIG. 16 shows the detailed circuit design implementation of the time domain subtractor, Relu activation function and delay element. Since V₄ is subtracted from three variables of V₁₋₃, then, each subtraction requires a separate digital circuit. The subtraction output can have a positive or a negative value. The Relu activation function passes the positive value while assigning the negative value to zero. Such implementation is developed using AND, XOR and inverter gates as highlighted in FIG. 16. In order to detect the difference between the two pulse widths, XOR gate is utilized and provides the subtraction output a₁₋₃. In order to determine the sign of the subtraction, V_{4-pw4} is inverted and then ANDED with V_{(1-3)-pw(1-3)} to generate a signal b₁₋₃. If any b₁₋₃=1, then the subtraction output is positive whereas when b₁₋₃=0, the subtraction output is negative. Finally, AND gate is used to pass the positive subtraction output as V_{o-pw1-3} while setting the negative subtraction output to zero. FIG. 17 shows the output waveform example of the subtraction and Relu function when V₁>V₄ and V₁<V₄. As depicted in FIG. 17, when V₁>V₄, the modulated pulse width of V_{1-pw1} is greater than the pulse width of V_{4-pw-4}. This means that the subtraction output is positive and passed with V_{o-pw1}=1.0 having a pulse width T_{o-pw1} that represents the difference between the pulse width of V_{1-pw1} and the pulse width of V_{4-pw-4}. On the other hand, when V₁<V₄, the subtraction difference is negative (b1=0) resulting in V_{opw1}=0. After that, the pulse width T_{o-pw1} of the signal V_{o-pw1} is scaled by a constant factor of 20 times that is chosen based on the subtraction output values between the expected and observed ones. Such large factor cannot be implemented using inverter delay. Consequently, two stages VTCs are utilized. Note that the V_{o-pw1} is considered as a clock signal for the VTC where it needs to be scaled. Each VTC circuit increases the pulse width by 10 times.

The ANN classifier has been designed and simulated in 65 nm CMOS technology with a supply voltage of 1V except the 5×4 and 4×4 weight matrices that operate at a supply voltage of 0.3 V. The input voltages Vᵢₙ₁₋₄ have a range of 0.0 V to 1.0 V in addition to V_{bias}=1.0 V. The five input voltages are converted into modulated pulse width signals V_{pw1-5} that have pulse widths in the range of 165 ps to 2 ns. The modulated pulse width input signals Vₒ₁₋₄ of the second weight matrix have a pulse width in the range of 1.6 ns to 7.5 ns. The pulse width T₁ of V_{clk} is set to 3 ns and the pulse width T2 of ˜V_{clk-d} is set to 9 ns. The example ANN classifier using C3PU shown in FIG. 15 achieves an inference accuracy of 90% whereas ideal implementation of ANN classifier in MATLAB has an inference accuracy of 96.67%.

The advantage of utilizing a cross-coupling capacitor for storage and processing element is that it can perform simultaneously as a high density and a low energy storage. One operand in the C3PU can be stored in the capacitive unit. While the second operand can be a modulated pulse width signal using voltage-to-time converter. The multiplication outputs can be transferred to an output current using CMOS transistors and then integrated using current integrator op-amp. The 5×4 C3PU crossbar 200 was developed to run all data simultaneously realizing fully parallel vector-matrix multiplication in one cycle. The energy consumption of the 5×4 C3PU is 66.4 fJ/MAC at 0.3V voltage supply with an error of 5.4% in 65 nm technology. The inference accuracy for the ANN architecture has been evaluated using the example C3PU for an iris flower data set achieving a 90% classification accuracy.

Other variations are within the spirit of the present invention. Thus, while the invention is susceptible to various modifications and alternative constructions, certain illustrated embodiments thereof are shown in the drawings and have been described above in detail. It should be understood, however, that there is no intention to limit the invention to the specific form or forms disclosed, but on the contrary, the intention is to cover all modifications, alternative constructions, and equivalents falling within the spirit and scope of the invention, as defined in the appended claims.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate embodiments of the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

All references, including publications, patent applications, and patents, cited herein are hereby incorporated by reference to the same extent as if each reference were individually and specifically indicated to be incorporated by reference and were set forth in its entirety herein.

1. A system for performing analog multiply-and-accumulate (MAC) operations, the system comprising:
a first wordline to which a first analog input voltage is applied;
a voltage supply line having a supply voltage (VDD);
a first bitline;
a clock signal line;
a first current integrator op-amp connected to the first bitline and to the clock signal line; and
a first cross coupling capacitor processing unit (C3PU) connected to the first wordline, wherein the first C3PU comprises:
a first C3PU CMOS transistor comprising a first C3PU gate terminal, a first C3PU VDD terminal connected to the voltage supply line, and a first C3PU current output terminal connected to the first bitline; and
a first C3PU capacitive unit comprising a first C3PU cross coupling capacitor and a first C3PU gate capacitor, wherein the first C3PU cross coupling capacitor is connected between the first wordline and the first C3PU gate terminal, and wherein the first C3PU gate capacitor is connected between the first C3PU gate terminal and ground,
wherein the first C3PU CMOS transistor is configured to conduct a current that is proportional to voltage applied to the first C3PU gate terminal.

2. The system of claim 1, further comprising:
a second wordline to which a second analog input voltage is applied;
a second C3PU connected to the second wordline, wherein the second C3PU comprises:
a second C3PU CMOS transistor comprising a second C3PU gate terminal, a second C3PU VDD terminal connected to the voltage supply line, and a second C3PU current output terminal connected to the first bitline; and
a second C3PU capacitive unit comprising a second C3PU cross coupling capacitor and a second C3PU gate capacitor, wherein the second C3PU cross coupling capacitor is connected between the second wordline and the second C3PU gate terminal, and wherein the second C3PU gate capacitor is connected between the second C3PU gate terminal and ground,
wherein the second C3PU CMOS transistor is configured to conduct a current that is proportional to voltage applied to the second C3PU gate terminal.

3. The system of claim 2, comprising:
an array of M×N C3PUs, including the first C3PU and the second C3PU, arranged in a crossbar architecture comprising M rows, N columns, wherein each of M and N is an integer number equal to 2 or greater, and wherein each of the array of M×N C3PUs comprises:
a respective CMOS transistor comprising a respective gate terminal, a respective VDD terminal connected to the voltage supply line, and a respective current output terminal; and
a respective C3PU capacitive unit comprising a respective C3PU cross coupling capacitor and a respective C3PU gate capacitor, wherein the respective C3PU cross coupling capacitor is connected between the respective wordline and the respective C3PU gate terminal, and wherein the respective C3PU gate capacitor is connected between the respective C3PU gate terminal and ground,
wherein the respective CMOS transistor is configured to conduct a current that is proportional to voltage applied to the respective gate terminal;
M wordlines, including the first wordline and the second wordline;
N bitlines, including the first bitline; and
N current integrator op-amps, including the first current integrator op-amp,
wherein:
each of the C3PUs in each respective column of the C3PUs has an current output terminal that is connected to a respective bitline of the N bitlines for the respective column of the C3PUs; and
each of the C3PUs in each respective row of the C3PUs is connected to a respective wordline of the M wordlines for the respective row of the C3PUs; and
the array of C3PUs are connected to the supply voltage line; and
each of the bitlines of the N bitlines is connected to a respective one of the N current integrator op-amps.

4. The system of claim 3, wherein the array of M×N C3PUs comprises five rows and four columns.

5. The system of claim 3, wherein:
the VDD is within a range from 0.1-0.5 V;
the analog input voltage is within a range from 0.1-1 V;
an equivalent capacitance of the capacitive unit is within a range from 0.1-1;
a bias voltage provided by a wordline of the M wordlines, is within a range of 0-1 V; and
a size of each respective CMOS transistor is 200 nm±1000 nm/60 nm±100 nm.

6. The system of claim 3 wherein:
the VDD is 0.3 V;
the analog input voltage is within a range from 0.5-1 V;
an equivalent capacitance of each respective capacitive unit is within a range from 0.5-0.75 Femto-Farad; and
a bias voltage, provided by a wordline of the M wordlines, is 1 V.

7. The system of claim 1, wherein the CMOS transistor is configured to conduct current corresponding to a gate voltage applied to the CMOS transistor falling in a range of 0.45-0.75 V.

8. The system of claim 1 wherein the CMOS transistor is configured to conduct a drain-source current that is linearly proportional to a gate voltage applied to the CMOS transistor.

9. The system of claim 1 wherein a non-linear mode of the CMOS transistor corresponds to a gate voltage applied to the CMOS transistor falling in a range of 0.25-0.45 V, the non-linear mode corresponding to a drain-source current conducted by the CMOS transistor of less than 100 nA.

10. The system of claim 1, wherein the analog input voltage is modulated.

11. The system of claim 1, wherein the analog input voltage has a modulated pulse width.

12. The system of claim 11, further comprising a voltage-to-time converter (VTC) that generates the analog input voltage from an input voltage.

13. A method of mapping a crossbar architecture comprising N columns of M cross coupling capacitive units (C3PUs) to an artificial neural network (ANN), where ‘N’ and ‘M’ are positive integers greater than one, the method comprising:
mapping A rows of the crossbar architecture to A input nodes of an input layer of the ANN, where A is an integer greater than one and less than M;
mapping the A input nodes and a first bias node to B hidden nodes of a hidden layer, where B is an integer greater than one and less than A;
mapping the B hidden nodes and a second bias node to B output nodes of an output layer;
applying A input voltages to the A input nodes;
generating a plurality of weighting factors;
determining a minimum weight value, such that none of the weighting factors are less than zero; and
generating an output measurement based on the A input voltages.

14. The method of claim 13, wherein generating the output measurement comprises normalizing and mapping a feature set comprising A features to A voltage values.

15. The method of claim 13, wherein generating the output measurement comprises mapping the plurality of weighting factors to a plurality of capacitance ratios corresponding to an array of C3PUs making up the crossbar architecture.

16. The method of claim 15, wherein mapping the plurality of weighting factors to a plurality of capacitance ratios corresponding to array of C3PUs comprises:
generating the weighting factors by training a simulated ANN using the A voltage values in a simulated crossbar architecture.

17. The method of claim 13, wherein generating the output measurement further comprises:
applying an M×N weight matrix comprising the weighting factors and the minimum weight value to the A input voltages, according to the mapping of the input layer to the hidden layer;
generating B voltage levels for the B hidden nodes at least in part by summing and integrating over time N output currents generated by the N columns of C3PUs;
generating B output voltages by applying an N×N weight matrix comprising the weighting factors according to the mapping of the hidden layer to the output layer; and
classifying a feature set based at least in part on the B output voltages, the feature set corresponding to the A inputs to the input layer.

18. The method of claim 17, wherein classifying the feature set comprises:
integrating and summing the B output voltages; and
applying a sigmoid activation function to a result of integrating and summing the B output voltages.

19. The method of claim 13, further comprising converting each of the A input voltages into an analog input voltage having a modulate pulse width via a respective voltage-to-time converter (VTC).
